(19) United States
(12) Patent Application Publication
(10) Pub. No.: US 2024/0332012 A1
(43) Pub. Date: Oct. 3, 2024

(54) METHOD FOR MANUFACTURING SIC SUBSTRATE

(71) Applicant: JUSUNG ENGINEERING CO., LTD., Gwangju-Si, Gyeonggi-Do (KR)

(72) Inventor: Chul Joo HWANG, Gwangju-Si, Gyeonggi-Do (KR)

(21) Appl. No.: 18/290,757

(22) PCT Filed: Aug. 5, 2022
(86) PCT No.: PCT/KR2022/011722

§ 371 Date: Jan. 19, 2024

(30) Foreign Application Priority Data
Aug. 6, 2021 (KR) 10-2021-0104086

(51) Int. Cl. H01L 21/02

(52) U.S. Cl. CPC H01L 21/02529; H01L 21/02376; H01L 21/02381; H01L 21/02387; H01L 21/02422; H01L 21/02576; H01L 21/02579; H01L 21/0262

(57) ABSTRACT

Provided is a method for manufacturing an SiC substrate. The method for manufacturing the SiC substrate includes preparing a base, forming any one SiC thin film of an n-type SiC thin film or a p-type SiC thin film on the base, and separating the SiC thin film from the base. The forming of the SiC thin film includes injecting a source gas containing silicon (Si) onto the base, performing primary purge of injecting a purge gas after the injection of the source gas is stopped, injecting a reactant gas containing carbon (C) after the stop of the primary purge, and performing secondary purge of injecting the purge gas after the injection of the reactant gas is stopped. Therefore, in accordance with an exemplary embodiment, the SiC thin film may be deposited at a low temperature to prepare the SiC substrate. Accordingly, power or time required for rising the temperature of the base to form the SiC thin film may be reduced.

### TECHNICAL FIELD

The present disclosure relates to a method for manufacturing an SiC substrate, and more particularly, to a method for manufacturing an SiC substrate by forming an SiC thin film through an atomic layer deposition method.

### BACKGROUND ART

A semiconductor device, for example, a field effect transistor includes a substrate, a pair of well regions provided in the substrate so as to be spaced apart from each other, a channel provided between the pair of well regions on the substrate, source and drain electrodes respectively provided on upper portions of the pair of well regions, a gate insulating layer formed between the source electrode and the drain electrode, and a gate electrode formed on an upper portion of the gate insulating layer.

An SiC substrate is used as a substrate for such a semiconductor device. The SiC substrate is prepared by depositing an SiC thin film on a base through chemical vapor deposition (CVD) and then separating the SiC thin film by removing the base.

However, in order to deposit the SiC thin film on the base through the chemical vapor deposition method, there is a limitation in that the base has to be heated to a high temperature. In this case, there is a limitation in that power required to deposit the SiC thin film increases, or it takes a lot of time.

### RELATED ART DOCUMENT

### Patent Document

(patent document 1) Korean Patent Registration No. 10-1001674

### DISCLOSURE OF THE INVENTIVE CONCEPT

### Technical Problem

The present disclosure provides a method for manufacturing an SiC substrate, which is capable of being manufactured at a low temperature.

The present disclosure also provides a method of manufacturing an SiC substrate, which is capable of being manufactured by depositing an SiC thin film at a low temperature.

### Technical Solution

In accordance with an exemplary embodiment, a method for manufacturing an SiC substrate includes: preparing a base; forming any one SiC thin film of an n-type SiC thin film or a p-type SiC thin film on the base; and separating the SiC thin film from the base, wherein the forming of the SiC thin film includes: injecting a source gas containing silicon (Si) onto the base; performing primary purge of injecting a purge gas after the injection of the source gas is stopped; injecting a reactant gas containing carbon (C) after the stop of the primary purge; and performing secondary purge of injecting the purge gas after the injection of the reactant gas is stopped.

The source gas may include at least one of SiH₄ or Si₂H₆.

The reactant gas may include at least one of C₃H₈ or SiH₃CH₃.

The injection of the reactant gas may include generating plasma.

The generating of the plasma may include injecting a hydrogen gas.

The forming of the SiC thin film may include repeatedly performing one process cycle, in which the injecting of the source gas, performing of the primary purge, the injecting of the reactant gas, and the performing of the secondary purge are sequentially performed.

The forming of the SiC thin film may include injecting a doping gas, wherein the doping gas may be injected during the injection of the source gas or injected before the performing of the primary purge after the injection of the source gas is stopped.

The doping gas may include: a gas containing at least one of N (nitrogen) or P (phosphorus); or a gas containing at least one of Al (aluminum), B (boron), or Ga (gallium).

The base may be made of a material comprising any one of graphite, Si (silicon), Ga (gallium), and glass.

### Advantageous Effects

In accordance with the exemplary embodiments, the SiC thin film may be deposited at the low temperature to prepare the SiC substrate. Accordingly, the power or time required for rising the temperature of the base to form the SiC thin film may be reduced.

### BRIEF DESCRIPTION OF THE DRAWINGS

Exemplary embodiments can be understood in more detail from the following description taken in conjunction with the accompanying drawings, in which:

FIG. 1 is a conceptual view illustrating a state in which an SiC thin film is formed on a base through a method in accordance with an exemplary embodiment;

FIG. 2 is a conceptual view illustrating a state in which the base and the SiC thin film are separated from each other to prepare an SiC substrate;

FIG. 3 is a view illustrating an example of a field effect transistor to which the SiC substrate manufactured through the method in accordance with an exemplary embodiment;

FIG. 4 is a conceptual view for explaining the method for forming the SiC thin film on the base in accordance with an exemplary embodiment; and

FIG. 5 is a schematic view illustrating a deposition device used in the method for manufacturing the SiC substrate in accordance with an exemplary embodiment.

### MODE FOR CARRYING OUT THE INVENTIVE CONCEPT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the figures, the dimensions of layers and regions are exaggerated for clarity of illustration. Like reference numerals refer to like elements throughout.

An embodiment of the present disclosure relates to a method for manufacturing a substrate. More particularly, an embodiment of the present disclosure relates to a method for manufacturing an SiC substrate, in which an SiC thin film is formed on a base through an atomic layer deposition (ALD) method. More specifically, an embodiment of the present disclosure relates to a method for manufacturing an SiC substrate, in which an n-type or p-type SiC thin film is formed on a base through an atomic layer deposition (ALD) method.

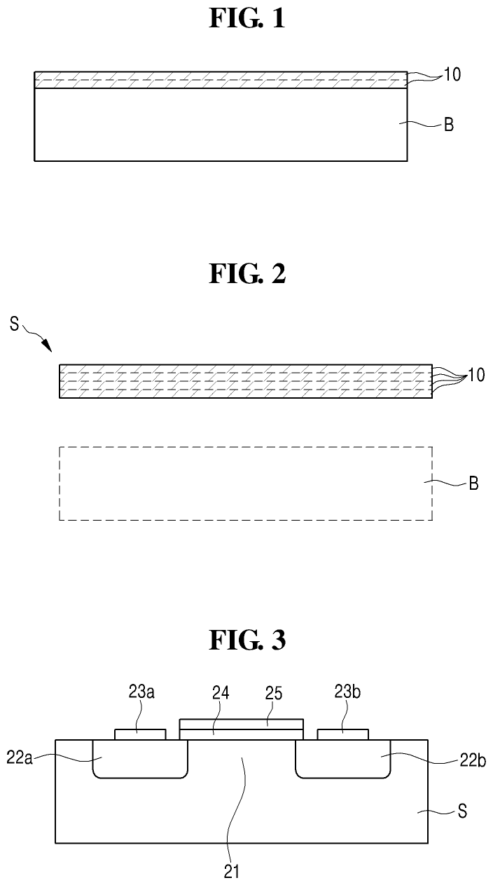

FIG. 1 is a conceptual view illustrating a state in which an SiC thin film is formed on a base through a method in accordance with an exemplary embodiment. FIG. 2 is a conceptual view illustrating a state in which the base and the SiC thin film are separated from each other to prepare an SiC substrate. FIG. 3 is a view illustrating an example of a field effect transistor to which the SiC substrate manufactured through the method in accordance with an exemplary embodiment.

Referring to FIG. 1, an SiC thin film 10 may be formed to be deposited on at least one surface of a base B, for example, a top surface of the base B.

The base B may be made of a material including any one of graphite, Si (silicon), Ga (gallium), and glass. More specifically, any one of a plate made of a graphite material, a wafer, and a plate made of a glass material may be used as the base B. In addition, the wafer used as the base B may be, for example, any one of a Si wafer, an SiC wafer, an SiO₂ (quartz) wafer, and a GaAS wafer.

The SiC thin film 10 may be formed through an atomic layer deposition (ALD) method and may be formed as an n-type or a p-type.

When the SiC thin film 10 having a predetermined thickness or a target thickness is formed on the base B, the SiC thin film may be separated from the base B as illustrated in FIG. 2, or the base B may be removed. The SiC thin film 10 separated from the base B or from which the base B is removed may be used as a substrate for manufacturing a semiconductor device. Accordingly, the SiC thin film 10 separated from the base B may be referred to as a substrate or an SiC substrate.

Hereinafter, for convenience of description, as illustrated in FIG. 1, the SiC thin film formed on an upper portion of the base B is referred to as reference numeral ‘10’. Here, since a plurality of SiC thin films are laminated, each of the plurality of SiC thin films may be referred to as reference numeral ‘10’.

In addition, when the formation of the SiC thin film 10 is finished, the base B may be removed or separated as described above. Here, the SiC thin film 10 from which the base B is removed or separated from the base B as illustrated in FIG. 2 is referred to as an SiC substrate, and the SiC substrate is referred to as reference symbol ‘S’.

The SiC thin film 10 formed through the method in accordance with an exemplary embodiment, that is, the SiC substrate S may be used as the substrate of the semiconductor device. For example, the SiC substrate in accordance with an exemplary embodiment may be used as the substrate S of the field effect transistor. When described in more detail with reference to FIG. 3, the field effect transistor may include a substrate S, a pair of well regions 22a and 22b provided in the substrate S so as to be spaced apart from each other in a width direction, a channel 21 provided between the pair of well regions 22a and 22b, source and drain electrodes 23a and 23b respectively provided on upper portions of the pair of well regions 22a and 22b, a gate insulating layer 24 formed between the source electrode 23a and the drain electrode 23b, and a gate electrode 25 formed on an upper portion of the gate insulating layer 24.

Here, the substrate S may be a substrate manufactured through the method in accordance with an exemplary embodiment. That is, the substrate S may be prepared by forming the SiC thin film 10 on the upper portion of the base B through the method in accordance with an exemplary embodiment (see FIG. 1) and then separating or removing the SiC thin film 10 from the base B (see FIG. 2). In addition, the SiC substrate S may be prepared in an n-type or p-type through the atomic layer deposition method.

The well regions 22a and 22b may be provided as the n-type or p-type. That is, when the substrate S is provided in the n-type, each of the well regions 22a and 22b may be provided in the p-type, and when the substrate S is provided in the p-type, each of the well regions 22a and 22b may be provided as the n-type. Here, the well region 22a formed to be in contact with the source electrode 23a or below the source electrode 23a may be a layer functioning as a source of the field effect transistor. In addition, the well region 22b formed to be in contact with the drain electrode 23b or below the drain electrode 23b may be a layer functioning as a drain of the field effect transistor.

The well regions 22a and 22b may be prepared by removing a portion of the thin film for forming the gate insulating layer formed on a top surface of the substrate S and then injecting a dopant raw material into the removed region. In addition, when the pair of well regions 22a and 22b are provided, a channel 21 is formed between the pair of well regions 22a and 22b.

The source and drain electrodes 23a and 23b are formed on the upper portion of the pair of well regions 22a and 22b, respectively. That is, the source electrode 23a is formed on the upper portion of one of the pair of well regions 22a, and the drain electrode 23b is formed on the upper portion of the other well region 22b. Here, each of the source and drain electrodes 23a and 23b may be made of a material including a metal, for example, at least one of Ti or Au.

The gate insulating layer 24 may be formed to be disposed on an upper portion of the channel 21 between the source electrode 23a and the drain electrode 23b. The gate insulating layer 24 may be made of any one of SiO₂, SiON, and Al₂O₃.

The gate electrode 25 may be formed on the upper portion of the gate insulating layer 24 so as to be disposed between the source electrode 23a and the drain electrode 23b. In this case, the gate electrode 25 may be made of a material including a metal, for example, may be made of a material including at least one of Ti or Au.

In the above, it has been described that the SiC substrate S manufactured through the method in accordance with an exemplary embodiment is used as the substrate of the field effect transistor as an example. However, the exemplary embodiment is not limited thereto, and the SiC substrate may be used in various semiconductor devices.

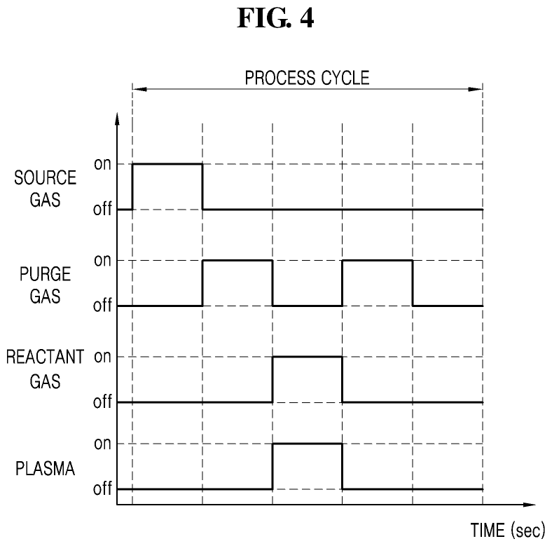

FIG. 4 is a conceptual view for explaining the method for forming the SiC thin film on the base in accordance with an exemplary embodiment.

Hereinafter, a method for forming the SiC thin film in accordance with an exemplary embodiment will be described with reference to FIGS. 1 and 4.

First, a base B is provided. Here, the base B may be, for example, a circular plate made of a graphite material.

When the base B is provided, an SiC thin film 10 is deposited on one surface, for example, a top surface of the base B as illustrated in FIG. 1. Here, the SiC thin film 10 may be formed through an atomic layer deposition (ALD) method, and a plurality of SiC thin films 10 may be laminated.

When the method for forming the SiC thin film 10 using the atomic layer deposition (ALD) method is described in more detail with reference to FIG. 4, the method for forming the SiC thin film 10 may include a process of injecting a source gas, a process (primary purge) of injecting a purge gas, a process of injecting a reactant gas, and a process (secondary purge) of injecting the purge gas. In this case, the injection of the source gas, the injection of the purge gas (primary purge), the injection of the reactant gas, and the injection of the purge gas (secondary purging) may be performed sequentially.

Here, the source gas may be a gas containing Si. In addition, a gas containing at least one of SiH₄ or Si₂H₆ may be used as, for example, the Si-containing gas. In addition, the reaction gas may be a gas containing C (carbon). In addition, a gas containing at least one of C₃H₈ or SiH₃CH₃ may be used as, for example, the C (carbon)-containing gas.

In addition, a doping gas is injected to form an n-type or p-type SiC thin film 10. Here, a gas containing at least one of a gas containing N (nitrogen) or a gas containing P (phosphorus) may be used as the doping gas. Alternatively, a gas containing at least one of a gas containing Al (aluminum), a gas containing B (boron), and a gas containing Ga (gallium) may be used as the doping gas. That is, when the n-type SiC thin film 10 is to be formed, at least one of the N (nitrogen)-containing gas or the P (phosphorus)-containing gas may be used as the doping gas. As another example, when the p-type SiC thin film 10 is to be formed, at least one of the Al (aluminum)-containing gas, the B (boron)-containing gas, or the Ga (gallium)-containing gas may be used as the doping gas.

The doping gas may be injected together when the source gas is injected or may be injected before the primary purging after the injection of the source gas is finished.

For example, when the source gas and the doping gas are injected together, the process of forming the SiC thin film 10 may be performed in order of the injection of the source gas and the doping gas, the injection of the purge gas (primary purge), the injection of the reactant gas, and the injection of the purge gas (secondary purging). Here, the doping gas may be mixed with the source gas and then be injected. Of course, the doping gas may be injected at a time point at which the source gas is injected, and a path through which the source gas is injected and a path through which the doping gas is injected may be different from each other. In the forming of the SiC thin film 10 by injecting the source gas and the doping gas together, ‘the injection of the source gas and the doping gas—the injection of the purge gas (primary purge)—the injection of the reactant gas—the injection of the purge gas (secondary purging)’ as described above to form the SiC thin film 10 may be defined as one process cycle.

For another example, the source gas and the doping gas may be injected to be divided into separate processes. That is, after the injection of the source gas is finished, the doping gas may be injected. In this case, the process of forming the SiC thin film may be performed in order of the injection of the source gas, the injection of the doping gas, the injection of the purge gas (primary purge), the injection of the reactant gas, and the injection of the purge gas (secondary purging). In the forming of the SiC thin film 10, ‘the injection of the source gas—the injection of the doping gas—the injection of the purge gas (primary purge)—the injection of the reactant gas—the injection of the purge gas (secondary purging)—the generation of the plasma’ as described above to form the SiC thin film 10 may be defined as one process cycle.

Plasma may be generated in the process of injecting the reactant gas in the process cycle as described above. In addition, at this time, a hydrogen gas may be injected to generate the plasma by the hydrogen gas. That is, when the reactant gas is injected, the hydrogen gas is injected together, and the hydrogen gas is discharged to generate the plasma by the hydrogen gas. As the plasma is generated during the injection of the reactant gas as described above, the SiC thin film may be deposited at a low temperature of approximately 300° C. to approximately 600° C.

In addition, the plasma generated by the hydrogen gas, that is, the hydrogen plasma, may remove impurities in the SiC thin film or in a space (reaction space) in which the SiC thin film is deposited. Here, the impurity may be, for example, a reaction byproduct due to reaction between the source gas and the reactant gas. The hydrogen plasma may decompose impurities such as the reaction byproduct due to the reaction between the source gas and the reactant gas. Accordingly, exhaust of the reaction byproduct is facilitated through an exhaust part connected to the reaction space. Accordingly, the impurities existing in the reaction space or the SiC thin film may be effectively removed.

As the above-described process cycle is performed several times, an atomic layer may be deposited several times. In other words, a plurality of SiC thin films 10 are laminated by the atomic layer deposition several times. In addition, the number of times of the process cycle to be performed may be adjusted to form the SiC thin film 10 having a target thickness.

On the other hand, in the related art, an SiC substrate was prepared by depositing the SiC thin film on the base B through a chemical vapor deposition method. Here, a support 200 that supports the base B or the base B was maintained at a high temperature of approximately 1,200° C. In other words, only when the temperature of the support 200 or the base B is maintained at a high temperature of approximately 1,200° C., the SiC thin film may be deposited on the top surface of the base B. In this case, there is a limitation in that the support 200 or the base has to be heated to a high temperature. Therefore, there is a limitation in that power required to deposit the SiC thin film increases, or it takes a lot of time.

However, in this embodiment, since the SiC thin film 10 is deposited through the atomic layer deposition method, the SiC thin film 10 may be deposited at a lower temperature when compared to the related art. Accordingly, the power required for depositing the SiC thin film 10 may be reduced.

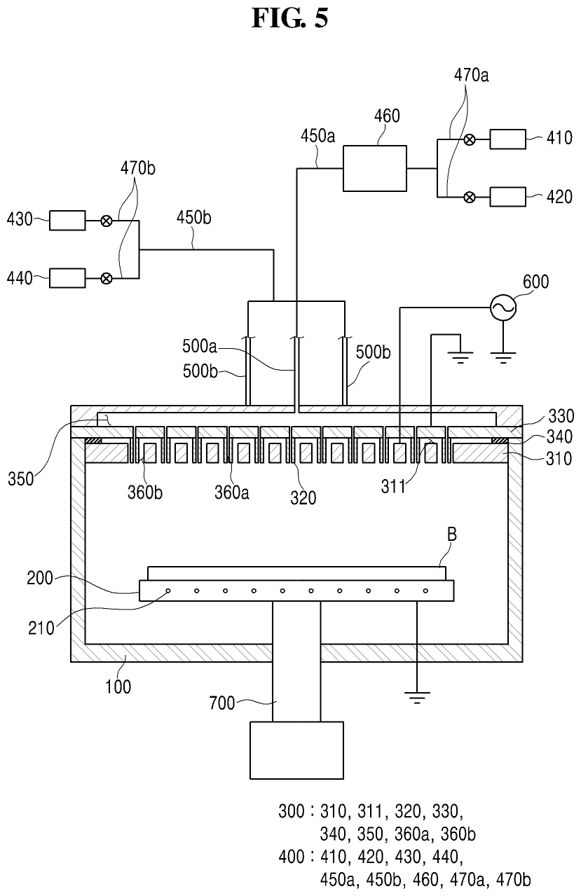

FIG. 5 is a schematic view illustrating a deposition device used in the method for manufacturing the SiC substrate in accordance with an exemplary embodiment.

The deposition device may be a device for depositing a thin film through an atomic layer deposition (ALD) method. More specifically, the deposition device may be a device for forming the SiC thin film 10 on the base B.

As illustrated in FIG. 5, the deposition device may include a chamber 100, a support 200 installed in the chamber 100 to support a base B, an injection part 300 disposed to face the support 200 and injecting a gas for processes (hereinafter, referred to as a process gas) into the chamber 100, a gas supply part 400 configured to provide the process gas to the injection part 300, first and second gas supply tubes 500a and 500b connected to the injection part 300 so that the first and second gas supply tubes 500a and 500b have paths different from each other and configured to supply the gas provided from the gas supply part 400 to the injection part 300, and an RF power supply part 600 configured to apply power so that plasma is generated in the chamber 100.

In addition, the deposition device may further include a driving part 700 configured to operate the support 200 in at least one of elevating and rotating operations and an exhaust part (not shown) installed to be connected to the chamber 100.

The chamber 100 may include an inner space in which a thin film is disposed on the base B loaded into the chamber 100. For example, a cross-section thereof the chamber 100 may have a shape such as a quadrangular shape, a pentagonal shape, or a hexagonal shape. Of course, a shape of the inside of the chamber 100 may be changed in various manners, the shape of the inside of the chamber 100 may be provided to correspond to that of the base B.

The support 200 is installed inside the chamber 100 to face the injection part 300 and supports the base B loaded into the chamber 100. A heater 210 may be provided inside the support 200. Thus, when the heater 210 is operated, the base B seated on the support 200 and the inside of the chamber 100 may be heated.

In addition, a separate heater may be provided inside the chamber 100 or outside the chamber 100 in addition to the heater 210 provided in the support 200 as a means configured to heat the base B or the inside of the chamber 100.

The injection part 300 may include a first plate 310 having a plurality of holes (hereinafter, referred to as holes 311) arranged in an extension direction of the support 200 and defined to be spaced apart from each other and disposed to face the support 200 inside the chamber 100, a nozzle 320 provided so that at least a portion thereof is inserted into each of the plurality of holes 311, and a second plate 330 installed to be disposed between an upper well inside the chamber 100 and the first plate 310 inside the chamber 100.

In addition, the injection part 300 may further include an insulating part 340 disposed between the first plate 310 and the second plate 330.

The first plate 310 may have a plate shape extending in the extension direction of the support 200. In addition, the plurality of holes 311 are provided in the first plate 310, and each of the plurality of holes 311 may be provided to pass through the first plate 310 in a vertical direction. The plurality of holes 311 may be arranged in the extension direction of the first plate 310 or the support 200.

Each of the plurality of nozzles 320 may have a shape extending in the vertical direction, have a path through which a gas passes is provided therein, and have opened upper and lower ends. In addition, each of the plurality of nozzles 320 may be installed so that at least a lower portion thereof is inserted into the hole 311 provided in the first plate 310, and an upper portion thereof is connected to the second plate 330. Thus, the nozzle 320 may be described as a shape protruding downward from the second plate 330.

An outer diameter of the nozzle 320 may be provided to be less than an inner diameter of the hole 311. In addition, when the nozzle 320 is installed to be inserted into the hole 311, an outer circumferential surface of the nozzle 320 may be installed to be spaced apart from a peripheral well of the hole 311 (i.e., an inner well of the first plate 310). Thus, the inside of the hole 311 may be divided into an outer space of the nozzle 320 and an inner space of the nozzle 320.

In the inner space of the hole 311, the path in the nozzle 320 is a path through which the gas provided from the first gas supply tube 500a moves and is injected. In addition, in the inner space of the hole 311, the outer space of the nozzle 320 is a path through which the gas provided from the second gas supply tube 500b moves and is injected. Thus, hereinafter, the path within the nozzle 320 is referred to as a first path 360a, and the space outside the nozzle 320 within the hole 311 is referred to as a second path 360b.

The second plate 330 may be installed so that a top surface thereof is spaced apart from the upper well of the chamber 100, and a bottom surface thereof is spaced apart from the first plate 310. Thus, empty spaces may be provided between the second plate 330 and the first plate 310 and between the second plate 330 and the upper well of the chamber 100, respectively.

Here, an upper space of the second plate 330 may be a space (hereinafter, a diffusion space 350) in which the gas provided from the first gas supply tube 500a is diffused to move and may communicate with an upper opening of each of the plurality of nozzles 320. In other words, the diffusion space 350 is a space communicating with the plurality of first paths 360a. Thus, the gas passing through the first gas supply tube 500a may be diffused in the extension direction of the second plate 330 in the diffusion space 350 and then may pass through the plurality of first paths 360a and be injected downward.

In addition, a gun drill (not shown), which is a path through which gas moves, may be provided inside the second plate 330, and the gun drill may be connected to the second gas supply tube 500b and provided to communicate with the second path 360b. Thus, the gas provided from the second gas supply tube 500b may be injected toward the base B through the gun drill of the second plate 330 and the second path 360b.

The gas supply part 400 provides a gas that is necessary for depositing a thin film by an atomic layer deposition method. The gas supply part 400 includes a source gas storage part 410 in which a source gas is stored, a doping gas storage part 420 in which a doping gas is stored, a reactant gas storage part 430 in which a reactant gas reacting with the source gas is stored, and a purge gas storage part 440 in which a purge gas is stored. In addition, the gas supply part 400 may further include a hydrogen gas storage part (not shown) in which a hydrogen gas is stored.

Here, the purge gas stored in the purge gas storage part 440 may be, for example, an N₂ gas or an Ar gas.

In addition, the gas supply part 400 may include a first transfer tube 450a connecting the source gas storage part 410 and the doping gas storage part 420 to the first gas supply tube 500a and a second transfer tube 450b installed to connect the reactant gas storage part 430 and the purge gas storage part 440 to the second gas supply tube 500b.

In addition, the gas supply part 400 may further include a mixing part 460 for mixing the gas provided from the doping gas storage part 420 with the gas provided from the source gas storage part.

In addition, the gas supply part 400 may include a plurality of first connection tubes 470a connecting each of the source gas storage part 410 and the doping gas storage part 420 to the first transfer tube 450a, a valve installed in each of the plurality of first connection tubes 470a, a plurality of second connection tubes 470b connecting each of the reactant gas storage 430 and the purge gas storage part 4430 to the second transfer tube 450b, and a valve installed in each of the plurality of second connection tubes 470b.

In addition, the hydrogen gas storage part may be connected to the first transfer tube 450a, and a connection tube may be provided between the hydrogen gas storage part and the first transfer tube 450a.

The mixing part 460 may be provided to have an inner space in which the gas is capable of being mixed. In addition, the mixing part 460 may be installed to connect the first connection tube 470a connected to each of the source gas storage part 410 and the doping gas storage part 420 to the first transfer tube 450a. Thus, the source gas and the doping gas, which are introduced into the mixing part 460, may be mixed in the mixing part 460 and then transferred to the first gas supply tube 500a through the first transfer tube 450a. In this case, the source gas and the doping gas are introduced into the injection part 300 in the mixed state, and the mixed gas is injected through a first path 360a of the injection part 300.

Of course, without mixing the source gas with the doping gas, the source gas and the doping gas may be transferred to the first gas supply tube 500a with a time difference.

In the above description, it has been described that the source gas storage part 410 and the doping gas storage part 420 are connected to the same first transfer tube 450a and injected through the first path 360a. However, this embodiment is not limited thereto, and the source gas storage part 410 and the doping gas storage part 420 may be connected to be injected through different paths. For example, the source gas storage part 410 may be connected to the first transfer tube 450a, and the doping gas storage part 420 may be connected to the second transfer tube 450b. In this case, the source gas may be introduced into the first path 360a of the injection part 300 through the first transfer tube 450a and the first gas supply tube 500a and then be injected, and the doping gas may be introduced into the second path 360b of the injection part 300 through the second transfer tube 450b and the second gas supply tube 500b and then be injected.

Hereinafter, the method of manufacturing the SiC substrate in accordance with an exemplary embodiment will be described with reference to FIGS. 1, 2 and 5. In this case, the method for forming the n-type SiC thin film will be described as an example.

First, a heater 210 provided in a support 200 operates to heat the support 200. Here, the heater operates so that a temperature of the support 200 or a base B to be seated on the support 200 is, for example, approximately 300° C. to approximately 600° C.

Next, the base B, for example, an Si wafer is loaded into the chamber 100 so as to be seated on the support 200. Thereafter, when the base B seated on the support 200 reaches a target process temperature, for example, approximately 300° C. to approximately 600° C., the SiC thin film 10 is formed on the base B as illustrated in FIG. 1.

In this case, the SiC thin film 10 is formed using an atomic layer deposition method. That is, the SiC thin film 10 is formed on the base B through the atomic layer deposition performed in order of the injection of the source gas, the injection of the purge gas (primary purge), the injection of the reaction gas, and the injection of the purge gas (secondary purge).

Here, the doping gas may be mixed with the source gas and then be injected. In addition, plasma may be generated in the chamber 100 by injecting a hydrogen gas and operating an RF power supply part 600 during the injection of the reaction gas. In this case, the process cycle of forming the SiC thin film 10 through the atomic layer deposition method may be a cycle of ‘the injection of the source gas and doping gas—the injection of the purge gas (primary purge)—the injection of the reactant gas (generation of plasma)—the injection of the purge gas (secondary purge)’. Then, the above-described process cycle is repeated several times to form the SiC thin film 10 having a target thickness.

Hereinafter, the method for forming the SiC thin film 10 by injecting a process gas into the chamber 100 using an injection part 300 and a gas supply part 400 will be described in more detail.

First, the source gas and the doping gas are injected into the chamber 100. For this, the source gas stored in the source gas storage part 410 and the doping gas stored in the doping gas storage part 420 are supplied to the mixing part 460. Accordingly, the source gas and the doping gas are mixed in the mixing part 460. Here, the source gas may be a Si-containing gas, and the doping gas may be an N (nitrogen)-containing gas.

The mixed source gas of the source gas and the doping gas is introduced into a diffusion space 350 in the injection part 300 through a first transfer tube 450a and a first gas supply tube 500a. Then, the mixed source gas of the source gas and the doping gas is diffused in the diffusion space 350 and then passes through a plurality of nozzles 320, that is, a plurality of first paths 360a and is injected toward the base B.

In the above, it has been described that the source gas and the doping gas are mixed and injected. However, this embodiment is not limited thereto, and the source gas and the doping gas may be injected to be divided into separate processes.

When the injection of the source gas and the doping gas, i.e., the mixed gas is stopped or finished, the purge gas is provided through the purge gas storage part 440 to inject the purge gas into the chamber 100 (primary purge). Here, the purge gas discharged from the purge gas storage part 440 may pass through the second connection tube 470b, the second transfer tube 450b, and the second gas supply tube 500b and then be injected downward through a second path 360b.

Next, the reactant gas, for example, a C (carbon)-containing gas, is provided from the reactant gas storage part 430 and injected into the chamber 100. In this case, the reactant gas may be injected into the chamber 100 through the same path as the purge gas. That is, after passing through the second connection tube 470b, the second transfer tube 450b, and the second gas supply tube 500b, the reactant gas may be injected downward through the second path 360b. When the reactant gas is injected, a reaction between the source gas adsorbed on the base B and the reactant gas may occur to generate a reactant, i.e., SiC. In addition, the reactant is deposited or deposited on the base B, and thus, the SiC thin film 10 is deposited on the base B. Here, an n-type SiC thin film 10 is deposited by the doping gas adsorbed on the base B.

When the reactant gas is injected, the hydrogen gas may be injected into the chamber 100, the RF power supply part 600 may operate to apply RF power to a first plate 310. When the RF power is applied to the first plate 310, plasma may be generated in the second path 360b in the injection part 300 and in a space between the first plate 310 and the support 200.

When the reactant gas injection is stopped, the purge gas is supplied through the purge gas storage part 440 to inject the purge gas into the chamber 100 (secondary purging). In this case, by-products of the reaction between the source gas and the reactant gas may be discharged to the outside of the chamber 100 by the secondary purging.

The process cycle performed in the order of ‘the injection of the source gas and the doping gas, the injection of the purge gas (primary purge), the injection of the reactant gas, and the injection of the purge gas (secondary purge)’ as described above may be repeated several times. In addition, the number of times of the process cycle to be performed may be determined in accordance with the target thickness.

When the SiC thin film 10 having a target thickness is formed, the SiC thin film 10 and the base B are separated from each other as illustrated in FIG. 2. Here, for example, the SiC thin film 10 may be separated by removing the base B through a polishing method. Of course, this embodiment is not limited to the polishing method, and any method may be used as long as the base B is removed, or the SiC thin film 10 is separated from the base B.

When the SiC thin film 10 is separated from the base B in this manner, a substrate S that may be used as a substrate for a semiconductor device, i.e., an SiC substrate S is prepared. In addition, the SiC substrate S manufactured in this manner may be used as a substrate for manufacturing a semiconductor device, for example, a field effect transistor.

As described above, in the method for manufacturing the SiC substrate S in accordance with an exemplary embodiment, the SiC thin film 10 is deposited on the base through the atomic layer deposition method. Thus, the SiC thin film 10 may be deposited at a lower temperature when compared to the related art. Therefore, there is an effect that is capable of reducing power required to manufacture the SiC substrate S or to deposit the SiC thin film 10.

### INDUSTRIAL APPLICABILITY

In accordance with the exemplary embodiments, the SiC thin film may be deposited at the low temperature to prepare the SiC substrate. Accordingly, the power or time required for rising the temperature of the base to form the SiC thin film may be reduced.

1. A method for manufacturing an SiC substrate, the method comprising:
preparing a base;
forming any one SiC thin film of an n-type SiC thin film or a p-type SiC thin film on the base; and
separating the SiC thin film from the base,
wherein the forming of the SiC thin film comprises:
injecting a source gas containing silicon (Si) onto the base;
performing primary purge of injecting a purge gas after the injection of the source gas is stopped;
injecting a reactant gas containing carbon (C) after the stop of the primary purge; and
performing secondary purge of injecting the purge gas after the injection of the reactant gas is stopped.

2. The method for manufacturing an SiC substrate of claim 1, wherein the source gas comprises at least one of SiH₄ or Si₂H₆.

3. The method for manufacturing an SiC substrate of claim 1, wherein the reactant gas comprises at least one of C₃H₈ or SiH₃CH₃.

4. The method for manufacturing an SiC substrate of claim 1, wherein the injection of the reactant gas comprises generating plasma.

5. The method for manufacturing an SiC substrate of claim 4, wherein the generating of the plasma comprises injecting a hydrogen gas.

6. The method for manufacturing an SiC substrate of claim 1, wherein the forming of the SiC thin film comprises repeatedly performing one process cycle, in which the injecting of the source gas, performing of the primary purge, the injecting of the reactant gas, and the performing of the secondary purge are sequentially performed.

7. The method for manufacturing an SiC substrate of claim 1, wherein the forming of the SiC thin film comprises injecting a doping gas,
wherein the doping gas is injected during the injection of the source gas or injected before the performing of the primary purge after the injection of the source gas is stopped.

8. The method for manufacturing an SiC substrate of claim 7, wherein the doping gas comprises:
a gas containing at least one of N (nitrogen) or P (phosphorus); or
a gas containing at least one of Al (aluminum), B (boron), or Ga (gallium).

9. The method for manufacturing an SiC substrate of claim 1, wherein the base is made of a material comprising any one of graphite, Si (silicon), Ga (gallium), and glass.
